(19) United States
(12) Patent Application Publication
(10) Pub. No.: US 2024/0204020 A1
(43) Pub. Date: Jun. 20, 2024

(54) OPTICAL PACKAGE STRUCTURE AND METHOD FOR MANUFACTURING THE SAME

(71) Applicant: TONG HSING ELECTRONIC INDUSTRIES, LTD., Taipei City (TW)

(72) Inventors: CHIEN-HUNG LIN, Taipei City (TW); BAE-YINN HWANG, Taipei City (TW); WEN-FU YU, Taipei City (TW); WEI-LI WANG, Taipei City (TW)

(21) Appl. No.: 18/474,201

(22) Filed: Sep. 25, 2023

(30) Foreign Application Priority Data
Dec. 15, 2022 (TW) 111148117
Jun. 7, 2023 (TW) 112121184

(51) Int. Cl. H01L 27/146; H01L 31/0232

(52) U.S. Cl. CPC H01L 27/14625; H01L 27/14685; H01L 31/02327; H01L 2933/0058

(57) ABSTRACT

An optical package structure and a method for manufacturing the same are provided. The optical package structure includes an optical element, a bonding structural member, and a light transmittable member. The bonding structural member is bonded to a surface of the optical element. The bonding structural member includes a first bonding layer, a light-absorption layer, and a second bonding layer. The first bonding layer and the second bonding layer are made of an opaque material. The light-absorption layer is disposed between the first bonding layer and the second bonding layer. The light transmittable member is bonded to the bonding structural member and spaced apart from the optical element. The light-absorption layer is configured to absorb light emitted to the bonding structural member.

### CROSS-REFERENCE TO RELATED PATENT APPLICATION

This application claims the benefit of priorities to Taiwan Patent Application No. 1112121184, filed on Jun. 7, 2023, and Ser. No. 11/148,117, filed on Dec. 15, 2022. The entire content of each of the above identified applications is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an optical package structure, and more particularly to an optical package structure and a method for manufacturing the same that can effectively reduce a flare.

### BACKGROUND OF THE DISCLOSURE

A conventional optical package structure includes an optical element, a bonding layer, and a light transmittable layer. The optical element can be, for example, an image sensor or a display element. Taking a chip of the image sensor for example, the chip has a chip substrate and an image-sensing region. The image-sensing region is an optical function region of photosensitivity. The bonding layer is connected to the chip substrate and surrounds the image-sensing region in an annular manner. The light transmittable layer is disposed above the image-sensing region through the bonding layer, and allows external light to enter the image-sensing region of the chip for image sensing. However, when the light passes through the light transmittable layer at certain angles, a light reflection phenomenon may occur due to changes of a refractive index. If the light is reflected to the image-sensing region, a flare will be formed, and the accuracy of the image sensing is affected.

In addition, the display element (e.g., a micro display) has a light outputting region, or referred to as a display emitting region. The light outputting region is an optical function region for emitting light, such as a light emitting diode (LED), an organic light emitting diode (OLED), or a backlight. The emitted light may be partially refracted or reflected by a region outside of the optical function region, such as a packaging material or the bonding layer. When such light enters the human eye, people may feel a flare or a light spot outside of the optical function region. Therefore, the conventional optical package structure still has room for improvement.

### SUMMARY OF THE DISCLOSURE

In response to the above-referenced technical inadequacies, the present disclosure provides an optical package structure and a method for manufacturing the same, so as to reduce the occurrence of a flare.

In order to solve the above-mentioned problems, one of the technical aspects adopted by the present disclosure is to provide an optical package structure, which includes an optical element, a bonding structural member, and a light transmittable member. The bonding structural member is bonded to a surface of the optical element. The bonding structural member includes a first bonding layer, a light-absorption layer, and a second bonding layer. The first bonding layer and the second bonding layer are made of an opaque material, the light-absorption layer is disposed between the first bonding layer and the second bonding layer. The light transmittable member is bonded to the bonding structural member, and is spaced apart from the optical element. The light-absorption layer is configured to absorb light emitted to the bonding structural member.

In order to solve the above-mentioned problems, another one of the technical aspects adopted by the present disclosure is to provide a method for manufacturing an optical package structure, which includes processes of: forming a plurality of first bonding layers having an enclosed shape on a bonding surface of a flat-shaped light transmittable board; forming a plurality of light-absorption layers on the plurality of first bonding layers, respectively; forming a plurality of second bonding layers on the plurality of light-absorption layers, respectively; slicing the light transmittable board into a plurality of light transmittable members, wherein each of the light transmittable members includes one of the first bonding layers, one of the light-absorption layers and one of the second bonding layers, so as to form a bonding structural member; and providing a plurality of optical elements, orienting the bonding surface of the light transmittable members toward the optical element, bonding the second bonding layer to the plurality of optical elements, and configuring the bonding structural member to surround an optical function region of the optical elements.

In order to solve the above-mentioned problems, yet another one of the technical aspects adopted by the present disclosure is to provide a method for manufacturing an optical package structure, which includes processes of: forming a plurality of first bonding layers having an enclosed shape on a bonding surface of a flat-shaped light transmittable board; forming a plurality of light-absorption layers on the plurality of first bonding layers, respectively; forming a plurality of second bonding layers on the plurality of light-absorption layers, respectively, to form a plurality of bonding structural members, in which each of the bonding structural members including one of the first bonding layers, one of the light-absorption layers, and one of the second bonding layers; providing a wafer, orienting a bonding surface of the light transmittable board toward the wafer, the plurality of second bonding layers being bonded to the wafer, and each of the bonding structural members surrounds a plurality of optical function regions of the wafer; and slicing the light transmittable board and the wafer, so that the light transmittable board is divided into a plurality of light transmittable members, and the wafer is divided into a plurality of optical elements, in which each of the optical elements including one of the optical function regions, and the plurality of bonding structural members are bonded between the plurality of light transmittable members and the plurality of optical elements, respectively.

Therefore, in the optical package structure and the method for manufacturing the same provided by the present disclosure, since the structure of the bonding structural member is multi-layered, and the bonding structural member includes the light-absorption layer that is made of a light-absorption material, external light that enters the light transmittable member can be absorbed by the light-absorption layer. Hence, light is less likely to be reflected by the bonding structural member to the optical function region of the optical element, or the light from the optical function region is less likely to be refracted or reflected by a non-display region (such as a package material or a bonding layer). In this way, chances of forming a flare can be reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view showing a first bonding layer being formed on a light transmittable board according to the present disclosure;

FIG. 2 is a schematic cross-sectional view showing a light-absorption layer being formed on the first bonding layer according to the present disclosure;

FIG. 3 is a schematic cross-sectional view of a bonding structural member according to the present disclosure;

FIG. 4 is a schematic cross-sectional view of an optical package structure according to the present disclosure;

FIG. 5 is a schematic cross-sectional view showing manufacturing of the bonding structural member according to another embodiment of the present disclosure;

FIG. 6 is a schematic cross-sectional view of the bonding structural member according to another embodiment of the present disclosure; and

FIG. 7 is a schematic side view showing the optical package structure being applied to a display element according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

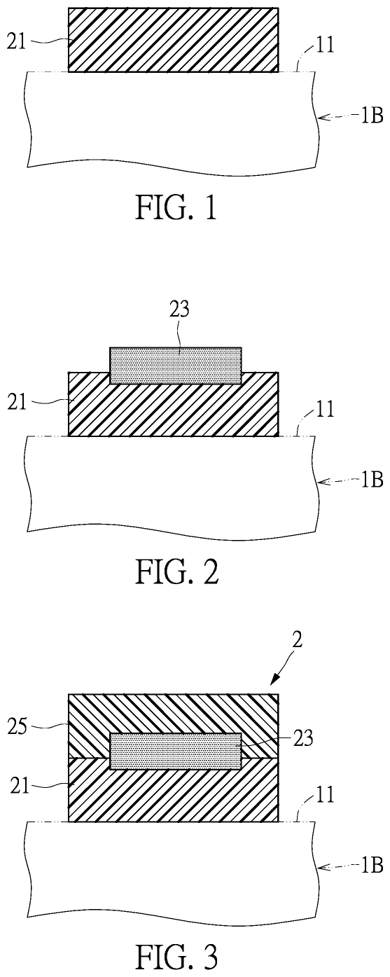

Referring to FIG. 1 to FIG. 4, a process of a method for manufacturing an optical package structure of the present disclosure is shown. The method is suitable for manufacturing an optical package structure for image sensing. The optical package structure is configured to be mounted on a circuit board (not shown).

In the following description, processes in the method for manufacturing the optical package structure of the present embodiment are illustrated. Firstly, as shown in FIG. 1, a first bonding layer 21 is formed on a bonding surface 11 of a flat-shaped light transmittable board 1B. From a top view, the first bonding layer 21 is substantially a square frame having a rectangular-enclosed shape (not shown). FIG. 1 is a schematic cross-sectional view only illustrating a single side of the first bonding layer 21.

Specifically, the flat-shaped light transmittable board 1B is provided, and then a material of the first bonding layer 21 is formed on the bonding surface 11 of the light transmittable board 1B in a coating way, a printing way, or an attaching way. The light transmittable board 1B allows light to pass therethrough, and its material can be, for example, glass or acrylic, but the present disclosure is not limited thereto. The first bonding layer 21 is made of opaque material, such as silicone or an epoxy resin, but is not limited thereto. The first bonding layers 21 can be arranged to be adjacent to or spaced apart from each other.

Reference is made to FIG. 2. A light-absorption layer 23 is further formed on the first bonding layer 21. In this embodiment, the material of the light-absorption layer 23 can be ink, an epoxy resin, or a photoresist material. The light-absorption layer 23 can be formed through a printing way, a dispensing way, or a spin coating way. The printing way is suitable for the ink, the dispensing way is suitable for the epoxy resin, and the spin coating way is suitable for the photoresist material. However, the present disclosure is not limited thereto. In the present disclosure, a vacuum coating way, such as evaporation, sputtering, or chemical vapor deposition (CVD), can also be used to form the light-absorption layer 23.

From a top view, the shape of the light-absorption layer 23 is preferably in cooperation with that of the first bonding layer 21, which is an enclosed rectangular ring (not shown). A width of the light-absorption layer 23 is smaller than a width of the first bonding layer 21. However, the present disclosure is not limited thereto. The shape of the light-absorption layer 23 can be a discontinuous dashed line. The light-absorption layer 23 can be linear-shaped and has an equal width, but is not limited thereto. For example, the light-absorption layer 23 can be linear-shaped or wave-shaped and has an unequal width.

Referring to FIG. 3, a second bonding layer 25 is formed on the light-absorption layer 23. The second bonding layer 25 is made of opaque material. A width of the second bonding layer 25 is larger than the width of the light-absorption layer 23. In other words, the width of the light-absorption layer 23 is smaller than the width of the second bonding layer 25, so that the second bonding layer 25 can fully cover the light-absorption layer 23. As such, the light-absorption layer 23 can be fully wrapped between the first bonding layer 21 and the second bonding layer 25, so as to form a bonding structural member 2. Furthermore, an inner edge of the light-absorption layer 23 can be adjacent to an inner edge of the first bonding layer 21. In this way, the light-absorption layer 23 can absorb light that is emitted to the bonding structural member 2, so that the light passing through or reflected by the bonding structural member 2 is reduced, and chances of forming a flare are reduced.

A height of the light-absorption layer 23 can be 20% to 80% of a total height of the bonding structural member 2. When a ratio of the light-absorption layer 23 relative to the bonding structural member 2 is increased, the light emitted to the bonding structural member 2 is more likely to be absorbed.

The shape of the second bonding layer 25 can be the same as the shape of the first bonding layer 21, which is an enclosed rectangular ring (not shown). However, the present disclosure is not limited thereto. The shape of the second bonding layer 25 can also be different from that of the first bonding layer 21.

In this embodiment, the width of the second bonding layer 25 is the same as the width of the first bonding layer 21. However, the present disclosure is not limited thereto. For example, the width of the second bonding layer 25 can be slightly smaller than the width of the first bonding layer 21, but is still larger than the width of the light-absorption layer 23. When the width of the second bonding layer 25 is smaller than the width of the first bonding layer 21, the second bonding layer 25 and the first bonding layer 21 can be stacked to form a stepped shape from a cross-sectional view, and advantages thereof will be described in detail later.

Moreover, the second bonding layer 25 can be directly formed on the first bonding layer 21 and the light-absorption layer 23. Alternatively, the second bonding layer 25 can be separately manufactured, and then is assembled or attached to the first bonding layer 21 and the light-absorption layer 23.

Next, the light transmittable board 1B is sliced into a plurality of light transmittable members 10. Each light transmittable member 10 has one of the first bonding layers 21, one of the light-absorption layers 23, and one of the second bonding layers 25, which is assembled as the bonding structural member 2.

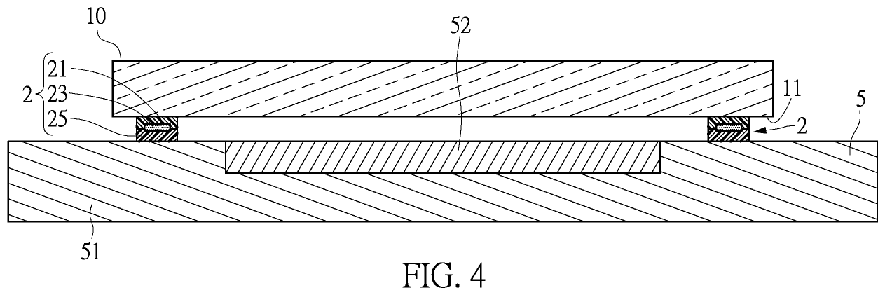

As shown in FIG. 4, finally, an optical element is provided. In this embodiment, the optical element is exemplified as an image sensor 5. The image sensor 5 includes a substrate 51, and an image-sensing region 52 on a top surface of the substrate 51. The image-sensing region 52 is an optical function region of the image sensor 5. The bonding surface 11 of the light transmittable member 10 is oriented toward the image sensor 5. The second bonding layer 25 is bonded to the image sensor 5, and the bonding structural member 2 is configured to surround the image-sensing region 52 of the image sensor 5. Each image-sensing region 52 of the image sensor 5 faces the bonding surface 11 of the light transmittable member 10. The bonding structural member 2 is bonded to a surface of the image sensor 5. The light transmittable member 10 is bonded to the bonding structural member 2, but the light transmittable member 10 and the image sensor 5 are spaced apart from each other. The light-absorption layer 23 is configured to absorb the light emitted to the bonding structural member 2.

In the present disclosure, the bonding structural member 2 includes the light-absorption layer 23 that is made of a light-absorption material. When external light enters the light transmittable member 10, the light can be absorbed by the light-absorption layer 23. Hence, the light is less likely to be reflected by the bonding structural member 2 to the image-sensing region 52 of the image sensor 5, thereby reducing the chances of forming a flare.

In addition, the second bonding layer 25 and the first bonding layer 21 could be stacked to form a stepped shape. The advantage of such configuration is that a distance between the image-sensing region 52 and an edge of the image sensor 5 can be reduced, so that the size of the image sensor 5 can be reduced. In other words, the image-sensing region 52 can become larger when being disposed on the image sensor 5 of a same area.

### Second Embodiment

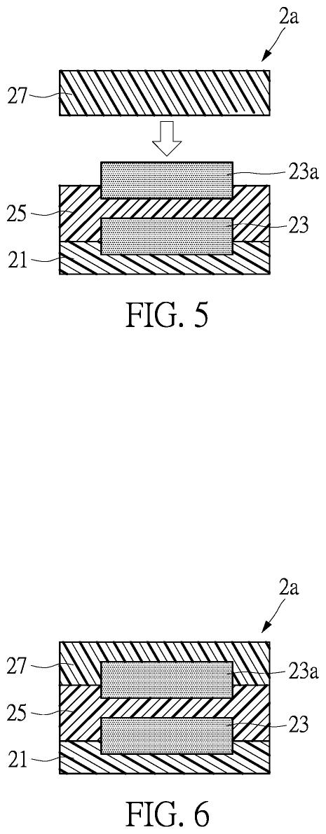

Referring to FIG. 5 and FIG. 6, a bonding structural member of a second embodiment of the present disclosure is shown. A bonding structural member 2a of this embodiment further includes an additional light-absorption layer 23a and a third bonding layer 27. The additional light-absorption layer 23a is disposed on the second bonding layer 25. The third bonding layer 27 is disposed on the additional light-absorption layer 23a. The advantage of the bonding structural member 2a in this embodiment is that incident light can be efficiently absorbed by the two light-absorption layers (23, 23a).

The shape of the third bonding layer 27 can be the same as the shape of the first bonding layer 21 or the shape of the second bonding layer 25, which is an enclosed rectangular ring (not shown). A width of the third bonding layer 27 is larger than a width of the additional light-absorption layer 23a, so as to cover the additional light-absorption layer 23a between the second bonding layer 25 and the third bonding layer 27. In this embodiment, the width of the third bonding layer 27 is equal to the width of the second bonding layer 25. However, the present disclosure is not limited thereto. For example, the width of the third bonding layer 27 can be smaller than the width of the second bonding layer 25, so that the first bonding layer 21, the second bonding layer 25, and the third bonding layer 27 are sequentially narrowed to form a stepped shape from a cross-sectional view.

Moreover, the plurality of first bonding layers 21 on the light transmittable board 1B can be spaced apart from each other, so as to form a plurality of bonding structural members 2a. However, the present disclosure is not limited thereto. The first bonding layers 21 can also be adjacent to each other. The light transmittable board 1B can be assembled to a non-sliced wafer (not shown) before being sliced together.

Specifically, the method for manufacturing the optical package structure of another embodiment can include processes as follows. Firstly, a plurality of first bonding layers 21 are formed on a bonding surface 11 of a flat-shaped light transmittable board 1B. Then, a plurality of light-absorption layers 23 are respectively formed on the plurality of the first bonding layers 21, and a plurality of second bonding layers 25 are respectively formed on the plurality of the light-absorption layers 23. Accordingly, a plurality of bonding structural members 2 are formed, each of which includes one of the first bonding layers 21, one of the light-absorption layers 23, and one of the second bonding layers 25.

A wafer (not shown) is provided with a plurality of image sensors 5 each having an image-sensing region 52. The bonding surface 11 of the light transmittable board 1B is oriented toward the wafer (not shown). The second bonding layers 25 are bonded to the wafer (not shown), and each of the bonding structural members 2 is configured to surround the image-sensing regions 52 on the wafer (not shown). Finally, the light transmittable board 1B and the wafer (not shown) are sliced, and the light transmittable board 1B is divided into a plurality of light transmittable members 10 that respectively correspond to the image-sensing regions 52 of the image sensors 5 of the wafer (not shown). The plurality of bonding structural members 2 are respectively connected to the plurality of the light transmittable members 10 and the plurality of the image sensors 5. The advantage of such a method is that the number of times of slicing can be reduced, and a plurality of optical package structures can be simultaneously formed.

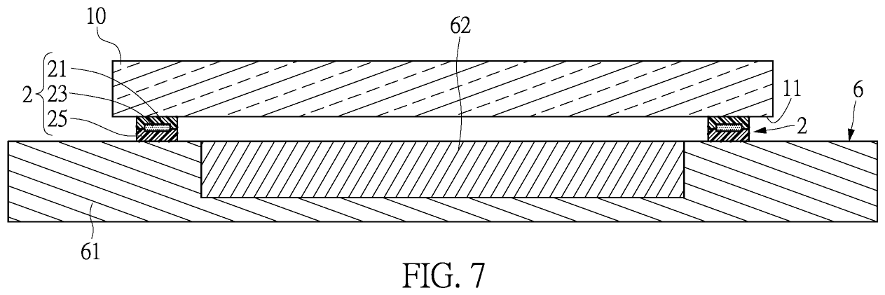

Referring to FIG. 7, the optical package structure of the present disclosure and the method for manufacturing the same can be applied to a display element 6. Different from the embodiment shown in FIG. 4, the optical element of this embodiment is the display element 6, which includes a substrate 61 and a display emitting region 62 on a top surface of the substrate 61. The display emitting region 62 is an optical function region of the display element 6. The display element 6 and the light transmittable member 10 are separated apart. The first bonding layer 21 of the bonding structural member 2 is bonded to the bonding surface 11 of the light transmittable member 10. Another side of the second bonding layer 25 is bonded to the substrate 61 of the display element 6. Therefore, in the optical package structure of this embodiment, by virtue of the light-absorption layer 23, light reflected to the human eye by the bonding structural member 2 can be reduced, thereby reducing the chances of forming a flare. In addition, the light from the display emitting region 62 is less likely to be refracted or reflected by a non-display region, such as a package material or a bonding layer. It should be noted that, the bonding structural member of this embodiment can be another configuration shown in FIG. 6.

### Beneficial Effects of the Embodiments

In conclusion, one of beneficial effects of the present disclosure is that, in the optical package structure and the method for manufacturing the same provided by the present disclosure, since the bonding structural member includes the light-absorption layer that is made of a light-absorption material, external light that enters the light transmittable member can be absorbed by the light-absorption layer. Hence, light is less likely to be reflected by the bonding structural member to the optical function region of the optical element, or the light from the optical function region is less likely to be refracted or reflected by the non-display region (such as a package material or a bonding layer). In this way, the chances of forming a flare can be reduced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An optical package structure, comprising:
an optical element;
a bonding structural member being bonded to a surface of the optical element, wherein the bonding structural member includes a first bonding layer, a light-absorption layer, and a second bonding layer, the first bonding layer and the second bonding layer are made of an opaque material, and the light-absorption layer is disposed between the first bonding layer and the second bonding layer; and
a light transmittable member being bonded to the bonding structural member and spaced apart from the optical element, wherein the light-absorption layer is configured to absorb light emitted to the bonding structural member.

2. The optical package structure according to claim 1, wherein a width of the light-absorption layer is smaller than a width of the first bonding layer, and a width of the second bonding layer is larger than the width of the light-absorption layer.

3. The optical package structure according to claim 1, wherein a width of the second bonding layer is smaller than a width of the first bonding layer, so that the bonding structural member is stacked to have a stepped shape.

4. The optical package structure according to claim 1, wherein the light-absorption layer is selected from the group consisting of ink, an epoxy resin, and a photoresist material.

5. The optical package structure according to claim 1, wherein a height of the light-absorption layer is 20% to 80% of a total height of the bonding structural member.

6. The optical package structure according to claim 1, wherein an inner edge of the light-absorption layer is arranged to be adjacent to an inner edge of the first bonding layer.

7. The optical package structure according to claim 1, wherein the bonding structural member further includes an additional light-absorption layer and a third bonding layer, the additional light-absorption layer is disposed on the second bonding layer, and the third bonding layer is disposed on the additional light-absorption layer.

8. The optical package structure according to claim 1, wherein the optical element is an image sensor, the image sensor includes a substrate and an image-sensing region disposed on a top surface of the substrate, and the image sensor and the light transmittable member are spaced apart from each other; wherein the first bonding layer is bonded to the light transmittable member, and another side of the second bonding layer is bonded to the substrate of the image sensor.

9. The optical package structure according to claim 1, wherein the optical element is a display element, the display element includes a substrate and a display emitting region disposed on a top surface of the substrate, and the display element and the light transmittable member are spaced apart from each other; wherein the first bonding layer is bonded to the light transmittable member, and another side of the second bonding layer is bonded to the substrate of the display element.

10. A method for manufacturing an optical package structure, comprising processes of:
forming a plurality of first bonding layers having an enclosed shape on a bonding surface of a flat-shaped light transmittable board;
forming a plurality of light-absorption layers on the plurality of first bonding layers, respectively;
forming a plurality of second bonding layers on the plurality of light-absorption layers, respectively;
slicing the light transmittable board into a plurality of light transmittable members, wherein each of the light transmittable members includes one of the first bonding layers, one of the light-absorption layers, and one of the second bonding layers, so as to form a bonding structural member; and
providing a plurality of optical elements, orienting the bonding surface of the light transmittable members toward the optical element, bonding the second bonding layer to the plurality of optical elements, and configuring the bonding structural member to surround an optical function region of the optical elements.

11. The method according to claim 10, wherein a formation process of the plurality of light-absorption layers is selected from the group consisting of a printing way, a dispensing way, and a spin coating way; wherein the printing way is suitable for ink, the dispensing way is suitable for an epoxy resin, and the spin coating way is suitable for a photoresist material.

12. The method according to claim 10, wherein the optical element is an image sensor, the image sensor includes a substrate and an image-sensing region disposed on a top surface of the substrate, and the image sensor and the light transmittable member are spaced apart from each other; wherein the first bonding layer is bonded between the light transmittable member and the substrate of the image sensor.

13. The method according to claim 10, wherein the optical element is a display element, the display element includes a substrate and a display emitting region disposed on a top surface of the substrate, and the display element and the light transmittable member are spaced apart from each other;
wherein the first bonding layer is bonded between the light transmittable member and the substrate of the display element.

14. A method for manufacturing an optical package structure, comprising processes of:
forming a plurality of first bonding layers having an enclosed shape on a bonding surface of a flat-shaped light transmittable board;
forming a plurality of light-absorption layers on the plurality of first bonding layers, respectively;
forming a plurality of second bonding layers on the plurality of light-absorption layers, respectively, so as to form a plurality of bonding structural members; wherein each of the bonding structural members includes one of the first bonding layers, one of the light-absorption layers, and one of the second bonding layers;
providing a wafer, orienting the bonding surface of the light transmittable board toward the wafer, bonding the plurality of second bonding layers to the wafer, and configuring each of the bonding structural members to surround a plurality of optical function regions of the wafer; and
slicing the light transmittable board and the wafer, so that the light transmittable board is divided into a plurality of light transmittable members, and the wafer is divided into a plurality of optical elements; wherein each of the optical elements includes one of the optical function regions, and the plurality of bonding structural members are bonded between the plurality of light transmittable members and the plurality of optical elements, respectively.

15. The method according to claim 14, wherein a formation process of the plurality of light-absorption layers is selected from the group consisting of a printing way, a dispensing way, and a spin coating way; wherein the printing way is suitable for ink, the dispensing way is suitable for an epoxy resin, and the spin coating way is suitable for a photoresist material.

16. The method according to claim 14, wherein the optical element is an image sensor, the image sensor includes a substrate and an image-sensing region disposed on a top surface of the substrate, and the image sensor and the light transmittable member are spaced apart from each other; wherein the first bonding layer is bonded between the light transmittable member and the substrate of the image sensor.

17. The method according to claim 14, wherein the optical element is a display element, the display element includes a substrate and a display emitting region disposed on a top surface of the substrate, and the display element and the light transmittable member are spaced apart from each other; wherein the first bonding layer is bonded between the light transmittable member and the substrate of the display element.
